(19) United States
(12) Patent Application Publication
(10) Pub. No.: US 2008/0186731 A1
(43) Pub. Date: Aug. 7, 2008

(54) LAMP

(76) Inventor: Morton Graham, Bolton (GB)

Correspondence Address: GAUTHIER & CONNORS, LLP, 225 FRANKLIN STREET, SUITE 2300, BOSTON, MA, 02110, US

(21) Appl. No.: 12/034,857

(22) Filed: Feb. 21, 2008

Related U.S. Application Data
(63) Continuation of application No. PCT/GB2006/003080, filed on Aug. 18, 2006.

(30) Foreign Application Priority Data
Aug. 24, 2005 (GB) 0517316.6
Feb. 15, 2006 (GB) 0602990.4

(51) Int. Cl. H01L 33/00

(52) U.S. Cl. 362/555

(57) ABSTRACT

A lamp comprising a base (10) having separate parts (11, 12) which may be brought together around, and to make contact with, an electrical supply cable (13). In the base (10) there is provided one or more LEDs and electrical circuitry, and a solid acrylic rod (18) is mounted in the base to receive light from the or each LED. The total internal reflection within the rod, and the lensing effect of a domed upper end (19) produce a beam of light equivalent to a standard incandescent light bulb but with low power input and increased durability when compared with an incandescent bulb. Several such lamps may be grouped together to form a downlighter, or spaced apart along the supply cable (13) and mounted externally on a building for decoration and display purposes.

### PRIORITY INFORMATION

This application is a continuation of International Application No. PCT/GB2006/003080 filed on Aug. 18, 2006 which claims priority to Great Britain Patent Application No. 0517316.6 filed on Aug. 24, 2005 and Great Britain Patent Application No. 0602990.4 filed on Feb. 15, 2006 all of which are incorporated by reference in their entirety herein.

### BACKGROUND OF THE INVENTION

1. Field of the Invention

This invention concerns a lamp which may be used singly or as a plurality of lamps grouped together or spaced along and in contact with an electrical supply cable, and is particularly useful as decorative lighting to emphasise, for example, the outline of a building.

2. Brief Description of the Prior Art

Such lamps, usually consist of a number of tungsten filament bulbs mounted in lamp holders and connected in parallel to an electrical supply cable. Tungsten filament lamps are notoriously unreliable, requiring frequent replacement of the bulbs, and consuming considerable quantities of the electrical supply.

### SUMMARY OF THE INVENTION

It is an object of the present invention to provide a lamp which can be used singly or as a plurality and where adequate brilliance is achieved but where power consumption is considerably reduced and with enhanced reliability and durability.

According to the present invention there is provided a lamp comprising a base containing at least one LED and associated electrical supply circuitry, a translucent rod mounted on, and upstanding from, the base, and being of a material which causes substantially total internal reflection of light from the or each LED entering a base end of the rod, the opposite end region of the rod being of reducing transverse cross section and of roughened surface texture.

The base may comprise at least two parts adapted to receive between them an insulated electrical supply cable.

The base may have contact pins adapted, when the base parts are brought together, to penetrate the cable insulation.

The translucent rod may be clear acrylic.

The opposite end region of the rod may be domed.

The domed opposite end region of the rod may be hemispherical, the remainder being of uniform cylindrical cross section.

The roughened surface texture of the opposite end region of the rod may extend part way down the rod from the domed end towards the base.

The opposite end region of the rod may have multiple flat faces.

The base may have an externally threaded portion to receive an internally threaded collar disposed around the base region of the rod.

A sealing ring may be provided between the collar and the threaded portion of the base to prevent ingress of moisture into the base.

The or each LED may be mounted on a printed circuit board housed within the base.

One part of the base may have means for attachment of the lamp to a mounting surface.

Several such lamps may be provided and grouped together in a closed array, or spaced apart along, and in contact with, the electrical supply cable.

The base may be formed as a cup partially enclosing the or each LED and of a heat dissipating material.

The or each LED may be adapted to display two or more colours selectively and in sequence.

### BRIEF DESCRIPTION OF THE DRAWINGS

An embodiment of the invention will be described, by way of example only, with reference to the accompanying drawings in which:

FIG. 1 illustrates a lamp made in accordance with a first embodiment of the invention and mounted on an electrical supply cable;

FIG. 2 is an exploded view showing the individual parts of the lamp;

FIG. 3 is a plan view of a second embodiment; and

FIG. 4 is a part sectional view of the second embodiment.

### DETAILED DESCRIPTION OF THE INVENTION

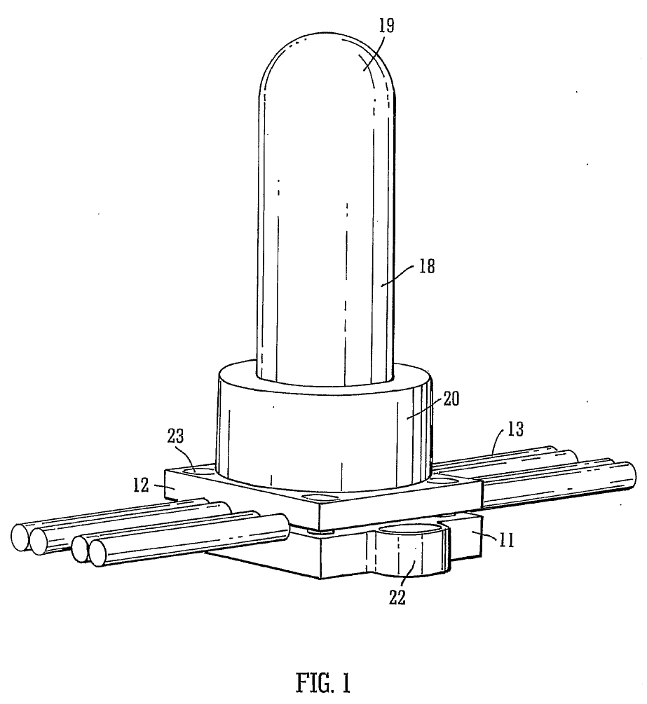

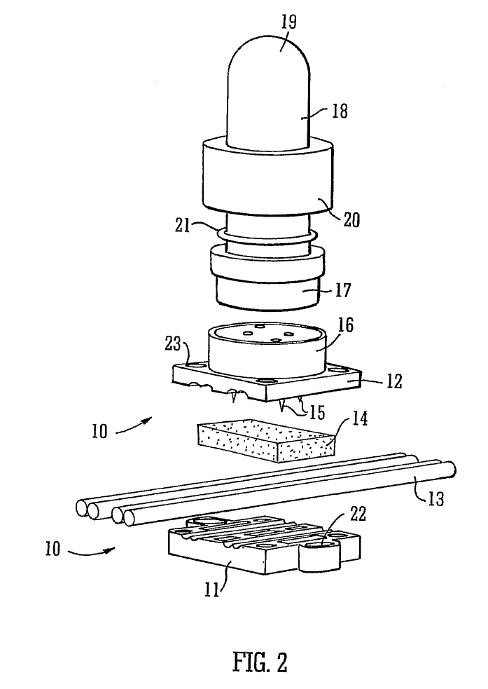

Referring now to FIGS. 1 and 2 the lamp comprises a base generally indicated at 10 which is adapted to contain at least one LED and associated electrical supply circuitry. The base 10 comprises a backing plate 11 and a front part 12, which are adapted to be brought together to entrap therebetween an electrical supply cable 13, a heat seal 14 being incorporated adjacent the cable 13. Contact pins 15 on the part 12 serve, when the parts of the base 10 are brought together, to penetrate the insulation on cable 13 thus to make contact therewith.

The part 12 of the base 10 has an upstanding portion 16 which is externally threaded and receives within it, as a resistance fit, a silicone collar 17.

Within the part 12 of the base, is housed the electrical circuitry and LED (not shown). The silicone collar 17 supports a solid clear acrylic rod 18 being of a material which displays total internal reflection of light entering the rod 18 from the LED in the base part 12. The upper end of rod 18 is domed as can be seen at 19 to act as a lens. The surface of the domed part 19 of the rod is roughened for a purpose to be described.

An internally threaded collar 20 locates over silicone collar 17 and attaches threadedly to the upstanding part 16 of base part 12, an ‘O’ ring 21 serving to provide a seal to prevent the ingress of moisture to the base and the LED and circuitry contained therein.

Typically, the rod 18 may be some 20 mm in diameter and some 60 mm in height. The base of the rod is preferably polished to ensure maximum transmission of light from the LED into the rod. A concentrated beam of light is produced by the lamp but is diffused by the roughened surface of the upper domed part 19 of the rod so that the light from the LED is not visible directly but appears as a strong beam of considerable brilliance when viewed end-on.

If required, the whole of the rod 18, save for its base, may have a roughened texture thus to diffuse the light outwardly through the entire surface of the rod, but maximum illumination is provided at the domed end due to its lensing effect.

Typically, one watt of power supplied to a single LED or multiple LED's will provide visible illumination equivalent to a 60 watt tungsten bulb.

The or each LED may be a so-called RGB chip providing selectable and changing colours if required.

In one form, several lamps as described may be mounted at spaced positions along the supply cable 13 and, as can be seen from FIG. 1, each base 10 is adapted to be mounted on a surface by means of screws introduced at 22.

The base parts may be clamped together using screws at the four corners of the base as illustrated at 23.

While the domed part 19 of the rod may be hemispherical as illustrated, to provide the maximum lensing effect, nevertheless, it may be of any form of reducing cross sectional shape and may consist, for example, of multiple flat faces each having a roughened surface.

The base 10 and collar 20 are preferably of a plastics material but could alternatively be of an alloy.

Whilst the rod is preferably of uniform cross-section throughout most of its length, it may, alternatively, be of varying cross-section. Again, whilst it is preferably circular in cross section, other shapes may be envisaged.

If the lamp is to be used singly then the base generally indicated at 10 may be replaced by a sealed cap having a threaded or bayonet arrangement similar to a traditional incandescent bulb so that the lamp may be introduced into a standard lamp holder. In this case, a transformer may be included in the base of the lamp thus to reduce the supplied voltage as required by the or each LED and its associated circuitry. Alternatively, voltage reduction may be conducted separately from the lamp, in the electrical supply.

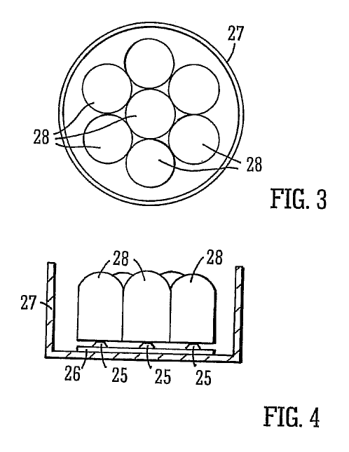

Referring to FIGS. 3 and 4 of the drawings in an alternative embodiment several LED's 25 may be mounted on a circuit board 26 housed in the bottom of a cup shaped base 27 of a heat dissipating material such as a metallic alloy. In this example the LED's are arranged in a closed array consisting of one central LED and six further LED's surrounding it. Mounted in the base 27 above each LED is a clear acrylic rod 28 similar to the rod 18 in FIGS. 1 and 2. Such a lamp may be used as a downlighter to replace standard ambient lighting such as incandescent or halogen lamps. Again, electrical power in the region of one watt shared equally between the seven LED's in this example will provide visible illumination equivalent to or greater than a 60 watt tungsten bulb. Clearly, the cup 27 is easily mounted on a surface such as a wall or ceiling.

We claim:

1. A lamp comprising a base containing at least one LED and associated electrical supply circuitry, a translucent rod mounted on and upstanding from the base, and being of a material which causes substantially total internal reflection of light from the or each LED entering a base end of the rod, the opposite end region of the rod being of reducing transverse cross-section and of roughened surface texture.

2. The lamp according to claim 1, wherein the base comprises at least two parts adapted to receive between them an insulated electrical supply cable.

3. The lamp according to claim 1, wherein the base includes contact pins adapted, when the parts are brought together, to penetrate the cable insulation.

4. The lamp according to claim 1, wherein the translucent rod is of solid clear acrylic.

5. The lamp according to claim 1, wherein the said opposite end region of the rod is domed.

6. The lamp according to claim 5, wherein the domed opposite end region of the rod is hemispherical, the remainder being of uniform cylindrical cross section.

7. The lamp according to claim 1, wherein the roughened surface texture of the opposite region of the rod extends also part way down the rod from the domed end towards the base.

8. The lamp according to claim 1, wherein the opposite end region of the rod has multiple flat faces.

9. The lamp according to claim 1, wherein the base has an externally threaded portion to receive an internally threaded collar disposed around a base region of the rod.

10. The lamp according to claim 9, wherein a sealing ring is provided between the internally threaded collar and the externally threaded portion of the base to prevent ingress of moisture into the base.

11. The lamp according to claim 1, wherein the or each LED is mounted on a printed circuit board housed within the base.

12. The lamp according to claim 1, wherein one part of the base has means for attachment of the lamp to a mounting surface.

13. The lamp according to claim 1, wherein several such lamps are provided and spaced along and in contact with an electrical supply cable.

14. The lamp according to claim 1, wherein several such lamps are provided and grouped together in a closed array.

15. The lamp according to claim 1, wherein the base is formed as a cup partially enclosing the or each LED and of a heat dissipating material.

16. The lamp according to claim 1, wherein the or each LED is adapted to display two or more colours selectively and in sequence.
